(19) United States
(12) Patent Application Publication
(10) Pub. No.: US 2005/0170290 A1
(43) Pub. Date: Aug. 4, 2005

(54) Method of manufacturing substrate for display and method of manufacturing display utilizing the same

(75) Inventor: Yoshio Dejima, Kawasaki (JP)

Correspondence Address: Patrick G. Burns, Esq.;GREER, BURNS & CRAIN, LTD., Suite 2500, 300 South Wacker Dr., Chicago, IL, 60606, US

(73) Assignee: FUJITSU DISPLAY TECHNOLOGIES CORPORATION

(21) Appl. No.: 10/848,610

(22) Filed: May 18, 2004

(30) Foreign Application Priority Data
Jan. 30, 2004 (JP) 2004-023281

(51) Int. Cl. G03F 7/00

(52) U.S. Cl. 430/312; 430/321; 430/320

(57) ABSTRACT

The invention relates to a method of manufacturing a substrate for a display and a method of manufacturing a display, and it is aimed at providing a display which has high luminance and which can achieve high display quality. A method of manufacturing a substrate for a display is provided in which an insulation film is formed on a gate bus line; a gate bus line terminal is formed on the insulation film; a protective film is formed on the gate bus line terminal; a resist layer formed on the projective film is patterned to form a resist pattern; and the resist pattern is used to form a first contact hole at which the gate bus line is exposed by removing the protective film and the insulation film and to form a second contact hole at which the gate bus line terminal is exposed by removing the protective film, the resist pattern above the second contact hole being formed with a thickness smaller than the thickness of the resist pattern in other regions.

### BACKGROUND OF THE INVENTION

1. Field of the Invention

The present invention relates to a method of manufacturing a substrate for a display and a method of manufacturing a display utilizing the same and, more particularly, to a method of manufacturing a substrate for a display having a plurality of bus lines intersecting each other with an insulation film interposed therebetween and a method of manufacturing display utilizing the same.

2. Description of the Related Art

Recently, liquid crystal displays are requested to have high definition and high quality display performance. Active matrix liquid crystal displays capable of achieving high display performance includes a TFT substrate having a thin film transistor (TFT), which is a switching device, and a pixel electrode at each pixel, an opposite substrate having a common electrode and color filter (CF) layers and a liquid crystal sealed between the substrates.

FIG. 17 shows a configuration of the neighborhood of a pixel and a terminal section of a TFT substrate according to the related art. As shown in FIG. 17, a TFT substrate 102 has gate bus lines 112 extending in the horizontal direction in the figure and drain bus lines 114 extending in the vertical direction in the figure such that they intersect the gate bus lines 112 with an insulation film, which is not shown, interposed between them. The right ends of the gate bus lines 112 in the figure are connected to gate bus line terminals 152. The upper end of the drain bus line 114 in the figure is connected to a drain bus line terminal 154.

TFTs 120 are formed in the vicinity of the intersections between the gate bus lines 112 and the drain bus lines 114. Parts of the gate bus lines 112 serve as gate electrodes of the TFTs 120, and drain electrodes 121 of the TFTs 120 are connected to the drain bus lines 114. A pixel electrode 116 is formed at each pixel region. The pixel electrodes 116 are connected to source electrodes 122 of the TFTs 120. Storage capacitor bus lines 118 extending in parallel with the gate bus lines 112 are formed such that they traverse pixel regions substantially in the middle thereof. On the storage capacitor bus lines 118, a storage capacitor electrode (intermediate electrode) 119 is formed at each pixel in connection to the pixel electrode 116.

There are demands for improvement of productivity and yield of manufacture of liquid crystal displays. In order to improve productivity and yield of manufacture, the TFT substrate 102 of the liquid crystal display is fabricated using a process employing five masks as described below. FIGS. 18A to 22D are sectional views taken in processes showing a method of manufacturing the TFT substrate 102 according to the related art. FIGS. 18A, 19A, 20A, 21A and 22A show a section in the neighborhood of a TFT 120 taken along the line W-W in FIG. 17, and FIGS. 18B, 19B, 20B, 21B and 22B show a section in the neighborhood of a gate bus line terminal 152 taken along the line X-X in FIG. 17. FIGS. 18C, 19C, 20C, 21C and 22C show a section in the neighborhood of a drain bus line terminal 154 taken along the line Y-Y in FIG. 17, and FIGS. 18D, 19D, 20D, 21D and 22D show a section in the neighborhood of a storage capacitor bus line 118 taken along the line Z-Z in FIG. 17.

First, as shown in FIGS. 18A to 18D, a metal layer (not shown) is formed on an entire surface of a glass substrate 110 and patterned using a first photo-mask to form gate bus lines (gate electrodes) 112 and storage capacitor bus lines 118.

Next, as shown in FIGS. 19A to 19D, an insulation film (gate insulation film) 130, an amorphous silicon (a-Si) film 131′ and a silicon nitride film (SiN film) are formed in the order listed throughout the substrate over the gate bus lines 112 and the storage capacitor bus lines 118. Subsequently, a resist is applied to the entire surface of the SiN film, and back exposure is performed from the bottom side of the glass substrate 110 using the gate bus lines 112 as a mask. Further, exposure and development is performed from the top side of the glass substrate 110 using a second photo-mask to form a resist pattern (not shown) on the gate bus lines 112 on a self alignment basis. The SiN film is then patterned using the resist pattern to form channel protection films 123.

Next, an n⁺ a-Si film and a metal layer (both of which are not shown) are formed throughout the substrate over the channel protection films 123. Subsequently, the metal layer, the n⁺ a-Si film, and the a-Si film 131′ are patterned using a third photo-mask. The channel protection films 123 serve as an etching stopper at an etching process involved in the patterning to leave the a-Si film 131′ unetched under the channel protection films 123. Thus, as shown in FIGS. 20A to 20D, active semiconductor layers 131, drain electrodes 121, source electrodes 122, storage capacitor electrodes 119, gate bus line terminals 152, drain bus line terminals 154 and drain bus lines 114 are formed.

Next, as shown in FIGS. 21A to 21D, a protection film 132 is formed throughout the substrate. Subsequently, the protection film 132 and the insulation film 130 are patterned using a fourth photo-mask to form contact holes 124 above the source electrodes 122, contact holes 125 above the end of the gate bus lines 112, contact holes 126 above the gate bus line terminals 152, contact holes 127 above the drain bus line terminals 154 and contact holes 128 above the storage capacitor electrodes 119. At this step, the contact holes 124, 126, 127 and 128 are formed by providing openings only in the protective film 132, whereas the contact holes 125 are formed by providing openings in both of the protective film 132 and the insulation film 130.

Next, a transparent conductive film (not shown) is formed throughout the substrate over the protective film 132. Subsequently, the transparent conductive film is patterned using a fifth photo-mask to form pixel electrodes 116, protective conductive films 153 on the gate bus line terminals 152 and protective conductive films 155 on the drain bus line terminals 154, as shown in FIGS. 22A to 22D. The pixel electrodes 116 are electrically connected to the source electrodes 122 through the contact holes 124 and are electrically connected to the storage capacitor electrodes 119 through the contact holes 128. The protective conductive films 153 are electrically connected to the gate bus lines 112 through the contact holes 125 and are electrically connected to the gate bus line terminals 152 through the contact holes 126. The protective conductive films 155 are electrically connected to the drain bus line terminals 154 through the contact holes 127. A TFT substrate 102 is completed through the above-described steps.

As thus described, according to the method of manufacturing a TFT substrate 102 in the related art, the contact holes 124, 126, 127 and 128 are formed by removing only the protective film 132 through etching and the contact holes 125 are formed by removing both of the protective film 132 and the insulation film 130 through etching at the same step (see FIGS. 21A to 21D). The formation of the contact holes 125 takes a longer time than the formation of the contact holes 124, 126, 127 and 128. Therefore, surfaces of the source electrodes 122, the gate bus line terminals 152, the drain bus line terminals 154 and the storage capacitor electrodes 119 exposed as a result of the formation of the respective contact holes 124, 126, 127 and 128 are laid bare to etching plasma until the formation of the contact holes 125 is completed. Since the surfaces of the source electrodes 122, the gate bus line terminals 152, the drain bus line terminals 154 and the storage capacitor electrodes 119 are damaged by the etching plasma, contact resistance between those elements and the pixel electrodes 116 and the protective conductive films 153 and 155 formed thereon increases to reduce electrical characteristics, which results in the problem of a reduction in display quality of the liquid crystal display.

Further, inner wall surfaces of the contact holes 124, 126, 127 and 128 are etched due to overetching. Since the contact holes 124, 126, 127 and 128 are thus likely to be oversized, the source electrodes 122, the gate bus line terminals 152, the drain bus line terminals 154 and the storage capacitor electrodes 119 to serve as etching stoppers must be designed with a large pattern size. Since the source electrodes 122 and the storage capacitor electrodes 119 are therefore large-sized, the aperture ratio of the pixels decreases, and this results in a problem in that the luminance of the liquid crystal display will be low and in that it will be difficult to provide the display with high definition.
Patent Document 1: Japanese Patent Laid-Open No. JP-A-H6-283416
Patent Document 2: Japanese Patent Laid-Open No. JP-A-2001-324725
Patent Document 3: Japanese Patent Laid-Open No. JP-A-2002-107762
Patent Document 4: Japanese Patent Laid-Open No. JP-A-2002-98995

### SUMMARY OF THE INVENTION

It is an object of the invention to provide a method of manufacturing a substrate for a display which makes it possible to achieve high luminance and high display characteristics and a method of manufacturing a display utilizing the same.

The above-described object is achieved by a method of manufacturing a substrate for a display, comprising the steps of forming a first electrode layer having a predetermined shape on a base substrate, forming a first insulation layer on the first electrode layer, forming a second electrode layer having a predetermined shape on the first insulation layer, forming a second insulation layer on the second electrode layer, forming a resist layer on the second insulation layer, patterning the resist layer to form a resist pattern having a predetermined shape, removing the first and second insulation layers using the resist pattern to form a first contact region in which the first electrode layer is exposed and removing the second insulation layer to form a second contact region in which the second electrode layer is exposed using the resist pattern, characterized in that the step of forming the resist pattern removes the resist layer on the first contact region and forms the resist pattern on the second contact region with a thickness smaller than the thickness of the resist pattern in other regions.

### BRIEF DESCRIPTION OF THE DRAWINGS

FIG. 1 shows a configuration of the neighborhood of a pixel and a terminal section of a TFT substrate fabricated using a method of manufacturing a substrate for a display according to a first embodiment of the invention;

FIGS. 2A to 2D are sectional views taken in processes showing the method of manufacturing a substrate for a display according to the first embodiment of the invention;

FIGS. 3A to 3D are sectional views taken in processes showing the method of manufacturing a substrate for a display according to the first embodiment of the invention;

FIGS. 4A to 4D are sectional views taken in processes showing the method of manufacturing a substrate for a display according to the first embodiment of the invention;

FIGS. 5A to 5D are sectional views taken in processes showing the method of manufacturing a substrate for a display according to the first embodiment of the invention;

FIG. 6 shows the method of manufacturing a substrate for a display according to the first embodiment of the invention;

FIG. 7 is an illustration for explaining halftone exposure used in the first embodiment of the invention;

FIG. 8 is an illustration for explaining halftone exposure used in the first embodiment of the invention;

FIGS. 9A to 9D are sectional views taken in processes showing the method of manufacturing a substrate for a display according to the first embodiment of the invention;

FIGS. 10A to 10D are sectional views taken in processes showing the method of manufacturing a substrate for a display according to the first embodiment of the invention;

FIGS. 11A to 11D are sectional views taken in processes showing the method of manufacturing a substrate for a display according to the first embodiment of the invention;

FIGS. 12A to 12D are sectional views taken in processes showing the method of manufacturing a substrate for a display according to the first embodiment of the invention;

FIGS. 13A to 13D are sectional views taken in processes showing the method of manufacturing a substrate for a display according to the first embodiment of the invention;

FIG. 14 is a sectional view taken in a process showing a method of manufacturing a substrate for a display according to a second embodiment of the invention;

FIGS. 15A and 15B are sectional views taken in processes showing the method of manufacturing a substrate for a display according to the second embodiment of the invention;

FIGS. 16A and 16C are sectional views taken in processes showing a method of manufacturing a substrate for a display according to a third embodiment of the invention;

FIG. 17 shows a configuration of the neighborhood of a pixel and a terminal section of a TFT substrate;

FIGS. 18A to 18D are sectional views taken in processes showing a method of manufacturing a TFT substrate according to the related art;

FIGS. 19A to 19D are sectional views taken in processes showing the method of manufacturing a TFT substrate according to the related art;

FIGS. 20A to 20D are sectional views taken in processes showing the method of manufacturing a TFT substrate according to the related art;

FIGS. 21A to 21D are sectional views taken in processes showing the method of manufacturing a TFT substrate according to the related art; and

FIGS. 22A to 22D are sectional views taken in processes showing the method of manufacturing a TFT substrate according to the related art.

### DESCRIPTION OF THE PREFERRED EMBODIMENTS

[First Embodiment]

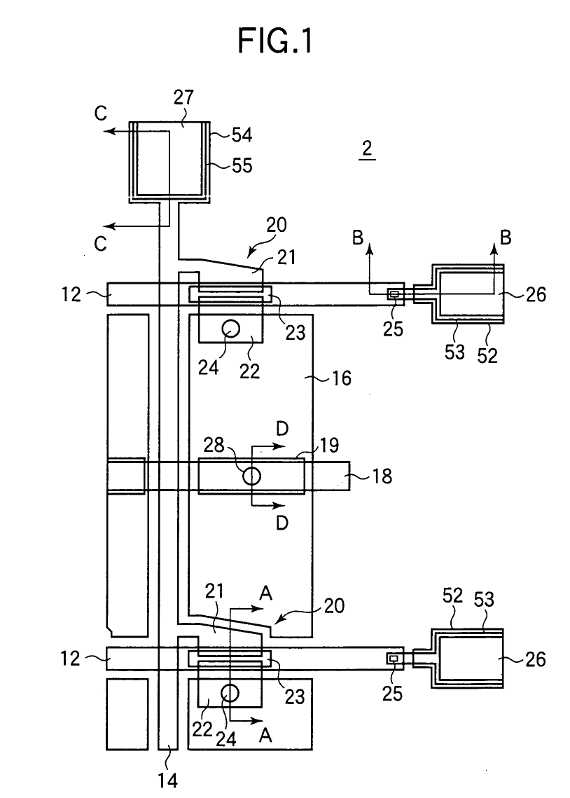

A description will now be made with reference to FIGS. 1 to 13D on a method of manufacturing a substrate for a display and a method of manufacturing a display utilizing the same in a first embodiment of the invention. A description will be first made on a configuration of a TFT substrate 2 fabricated using the method of manufacturing a substrate for a display of the present embodiment. FIG. 1 shows a configuration of the neighborhood of a pixel and a terminal section of the TFT substrate 2. As shown in FIG. 1, the TFT substrate 2 has a plurality of gate bus lines 12 (two of which are shown in FIG. 1) extending in the horizontal direction in the figure and a plurality of drain bus lines 14 (only one of which is shown in FIG. 1) extending in the vertical direction in the figure such that they intersect the gate bus lines 12 with an insulation film 30 (not shown in FIG. 1) interposed between them. The right ends of the gate bus lines 12 in the figure are electrically connected to respective gate bus line terminals 52. The gate bus line terminals 52 are formed of the same material as that of the drain bus lines 14. Protective conductive films 53 are formed above the gate bus line terminals 52. The protective conductive films 53 are electrically connected to the gate bus line terminals 52 through contact holes 26 and are electrically connected to the gate bus lines 12 through contact holes 25. Connection terminals of a gate bus line driving circuit are connected to the gate bus line terminals 52 (protective conductive films 53) at a later step to apply a predetermined gate pulse to each of the gate bus lines 12 sequentially.

The upper ends of the drain bus lines 14 in the figure are electrically connected to drain bus line terminals 54. The drain bus line terminals 54 are formed of the same material as that of the drain bus lines 14. Protective conductive films 55 are formed above the drain bus line terminals 54. The protective conductive films 55 are electrically connected to the drain bus line terminals 54 through contact holes 27. Connection terminals of a drain bus line driving circuit are connected to the drain bus line terminals 54 (protective conductive films 55) at a later step to apply a predetermined gradation voltage to each of the drain bus lines 14.

TFTs 20 are formed in the vicinity of the intersections between the gate bus lines 12 and the drain bus lines 14. Parts of the gate bus lines 12 serve as gate electrodes of the TFTs 20, and drain electrodes 21 of the TFTs 20 are electrically connected to the drain bus lines 14. A pixel electrode 16 is formed at each pixel region. The pixel electrodes 16 are electrically connected to source electrodes 22 of the TFTs 20 through contact holes 24. Storage capacitor bus lines 18 extending in parallel with the gate bus lines 12 are formed of the same material as that of the gate bus lines 12 such that they traverse pixel regions substantially in the middle thereof. A storage capacitor bus line 18 serves as one electrode of a storage capacitor. On the storage capacitor bus lines 18, a storage capacitor electrode (intermediate electrode) 19 is formed of the same material as that of the drain bus lines 14 at each pixel, the electrode serving as another electrode of the storage capacitor. The storage capacitor electrodes 19 are electrically connected to the pixel electrodes 16 through contact holes 28.

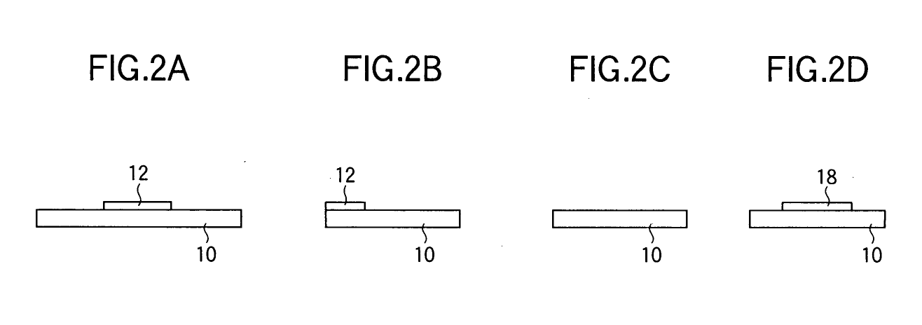

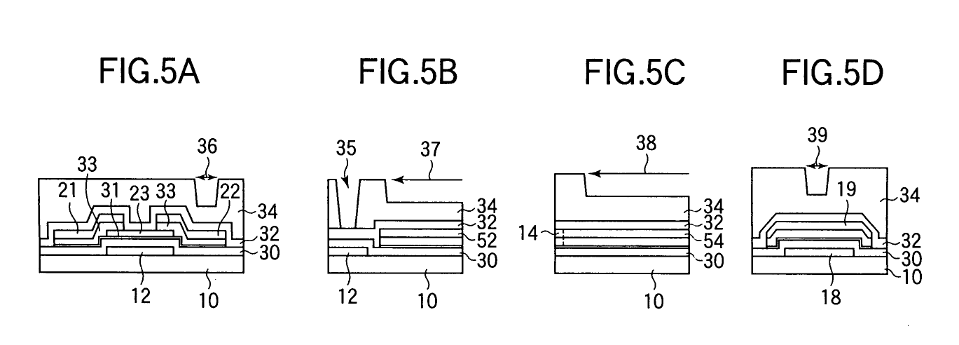

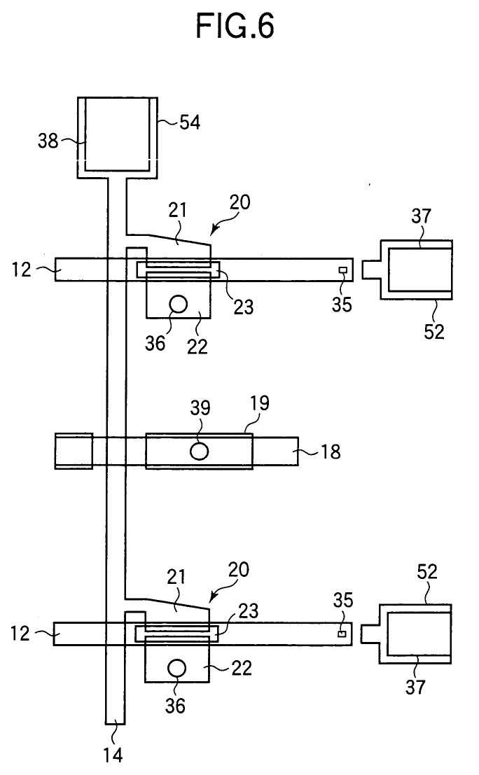

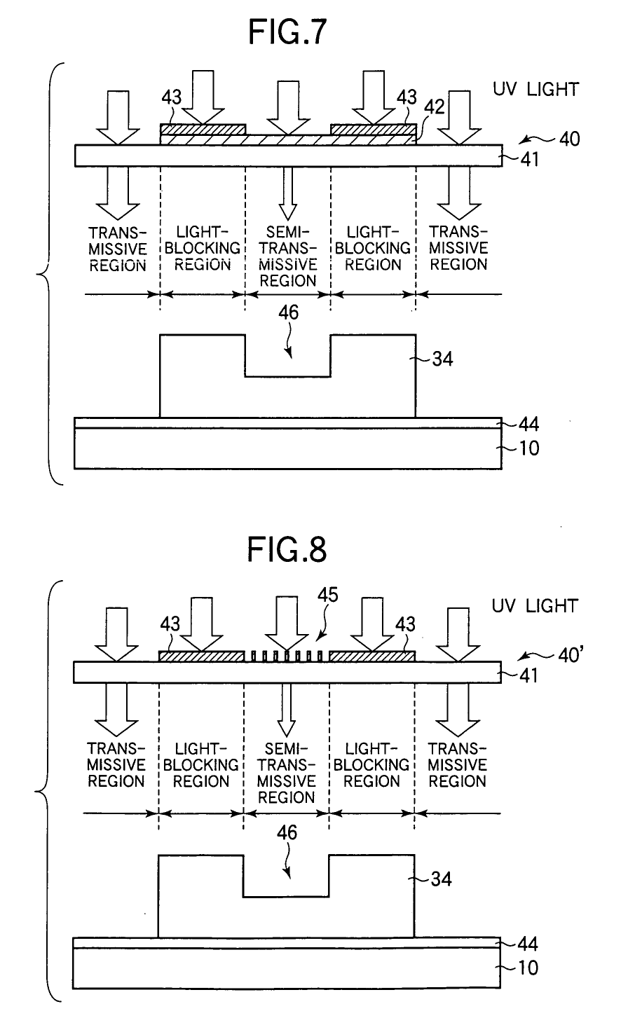

A description will now be made on a method of manufacturing the substrate for a display and a method of manufacturing a display utilizing the same according to the present embodiment. FIGS. 2A to 5D and FIGS. 9A to 13D are sectional views taken in processes showing the method of manufacturing a substrate for a display and the method of manufacturing a display utilizing the same according to the present embodiment. FIGS. 2A, 3A, 4A, 5A, 9A, 10A, 11A, 12A and 13A show a section in the neighborhood of a TFT 20 taken along the line A-A in FIG. 1, and FIGS. 2B, 3B, 4B, 5B, 9B, 10B, 11B, 12B and 13B show a section in the neighborhood of a gate bus line terminal 52 taken along the line B-B in FIG. 1. FIGS. 2C, 3C, 4C, 5C, 9C, 10C, 11C, 12C and 13C show a section in the neighborhood of a drain bus line terminal 54 taken along the line C-C in FIG. 1, and FIGS. 2D, 3D, 4D, 5D, 9D, 10D, 11D, 12D and 13D show a section in the neighborhood of a storage capacitor bus line 18 taken along the line D-D in FIG. 1. FIG. 6 shows a configuration of the TFT substrate 2 when viewed in a direction perpendicular to the surface of the substrate at the step shown in FIGS. 5A to 5D. FIGS. 7 and 8 are conceptual illustrations for explaining halftone exposure used in the present embodiment.

First, as shown in FIGS. 2A to 2D, a metal layer (not shown) is formed on an entire surface of, for example, a glass substrate (base substrate) 10 which is transparent and which has insulating properties, and the layer is patterned using a first photo-mask to form gate bus lines (gate electrodes) 12 and storage capacitor bus lines 18 (first electrode layer).

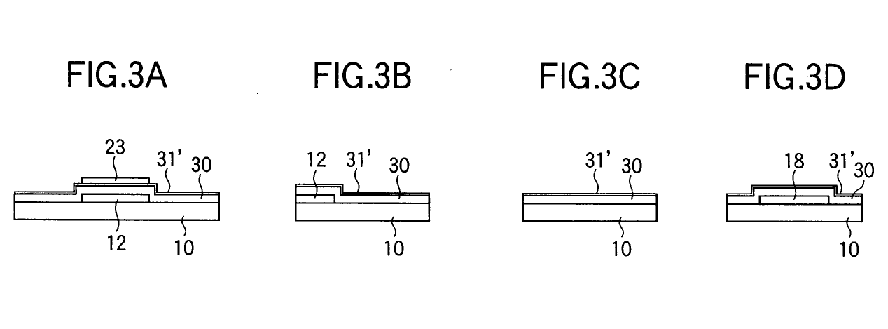

Next, as shown in FIGS. 3A to 3D, an insulation film (first insulation layer) 30, an a-Si film 31′ and a SiN film (not shown) are formed in the order listed throughout the substrate over the gate bus lines 12 and the storage capacitor bus lines 18. Si₃N₄, SiO₂ or SiON is used as a material to form the insulation film 30. Subsequently, a resist is applied to the entire surface of the SiN film, and back exposure is performed from the bottom side of the glass substrate 10 using the gate bus lines 12 as a mask. Further, exposure and development is performed from the top side of the glass substrate 10 using a second photo-mask to form a resist pattern (not shown) on the gate bus lines 12 on a self alignment basis. The SiN film is then patterned using the resist pattern to form channel protection films 23.

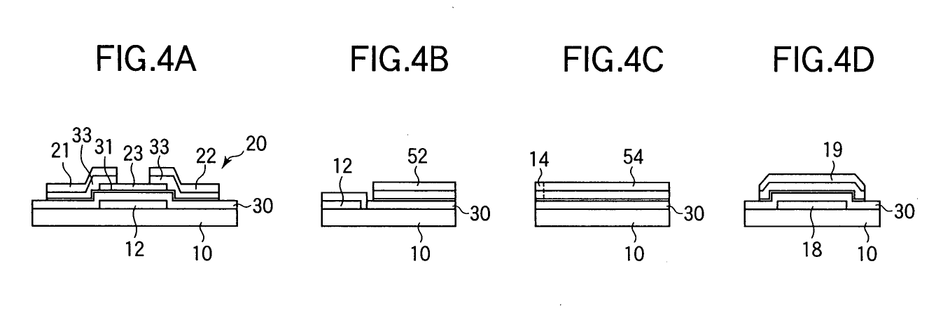

Next, an n⁺ a-Si film and a metal layer (both of which are not shown) are formed throughout the substrate over the channel protection films 23. Subsequently, the metal layer, the n⁺ a-Si film and the a-Si film 31′ are patterned using a third photo-mask. Since the channel protection films 23 serve as an etching stopper at an etching process involved in the patterning, the a-Si film 31′ are left unetched under the channel protection films 23. Thus, as shown in FIGS. 4A to 4D, active semiconductor layers 31 and n-type impurity semiconductor layers 33 of TFTs 20, drain electrodes 21, source electrodes 22, storage capacitor electrodes 19, gate bus line terminals 52, drain bus line terminals 54 and drain bus lines 14 (second electrode layer) are formed.

Next, as shown in FIGS. 5A to 5D and FIG. 6, a protection film (second insulation layer) 32 is formed throughout the substrate. Si₃N₄, SiO₂, or SiON is used as a material to form the protection film 32. For example, a positive novolac type resist is then applied to the entire surface of the protective film 32 to form a resist layer (not shown). Subsequently, halftone exposure is performed on the resist layer using a fourth photo-mask as will be described later to perform development. Thus, the resist layer is removed to form openings 35 in regions thereof located above the right ends of the gate bus lines 12 in FIG. 6, and a resist pattern 34 having a predetermined shape is formed. Recessed portions 36 are formed on the resist pattern 34 in regions thereof located above the source electrodes 22 by making the thickness in those regions smaller than that in other regions. Similarly, recessed portions 37 are formed in regions above the gate bus line terminals 52; recessed portions 38 are formed in regions above the drain bus line terminals 54; and recessed portions 39 are formed in regions above the storage capacitor bus lines 19.

The step of performing the above-described halftone exposure will now be described. As shown in FIG. 7, a fourth photo-mask (halftone mask) 40 used for the halftone exposure has a two-layer structure on a silica substrate 41 thereof, the structure consisting of a semi-transmissive film 42 which transmits UV light incident thereupon while attenuating the intensity of the same and a light-blocking film 43 which blocks incident UV light. The semi-transmissive film 42 and the light-blocking film 43 are stacked on the silica substrate 41 in the order listed, for example, and are patterned in predetermined respective shapes. The photo-mask 40 has transmissive regions in which neither semi-transmissive film 42 nor light-blocking film 43 is formed to transmit UV light with a predetermined light transmittance, semi-transmissive regions in which the semi-transmissive film 42 is formed to transmit UV light with a light transmittance lower than the light transmittance in the transmissive regions, and light-blocking regions in which the semi-transmissive film 42 and the light-blocking film 43 (or only the light-blocking film 43) are formed to block UV light (the intensity of UV light is indicated by the thickness of an arrow in FIG. 7). When the resist layer is exposed using the photo-mask 40, the resist layer is substantially completely exposed in regions thereof associated with the transmissive regions of the photo-mask 40 because it is subjected to a dose of exposure equal to or greater than a required dose of exposure, whereas the exposure of the resist layer is incomplete in regions thereof associated with the semi-transmissive regions of the photo-mask 40 because it is subjected to a dose of exposure smaller than the required dose of exposure. Therefore, when the resist layer is developed after the exposure, the resist layer is removed in the regions associated with the transmissive regions, and a resist pattern 34 is thus provided in which the thickness in regions associated with the semi-transmissive regions is smaller than that in other regions.

A resist pattern 34 which is formed on a film 44 to be etched on the glass substrate 10 after the developing step is shown in the lower part of FIG. 7. In a region of the resist pattern 34 associated with a semi-transmissive region of the photo-mask 40, a recessed portion 46 is formed at which the thickness of the pattern is smaller than that in a region associated with a light-blocking region of the photo-mask 40.

Instead of the photo-mask 40, a photo-mask 40′ having a single layer structure without the semi-transmissive film 42 as shown in FIG. 8 may be used. The photo-mask 40′ has transmissive regions in which no light-blocking film 43 is formed, light-blocking regions in which the light-blocking film 43 is formed, and semi-transmissive regions which has a light-blocking film 43 formed with slits 45 and which transmit UV light with a light transmittance lower than the light transmittance of the transmissive regions. A resist pattern 34 having recessed portions 46 similar to that described above can be obtained using the photo-mask 40′.

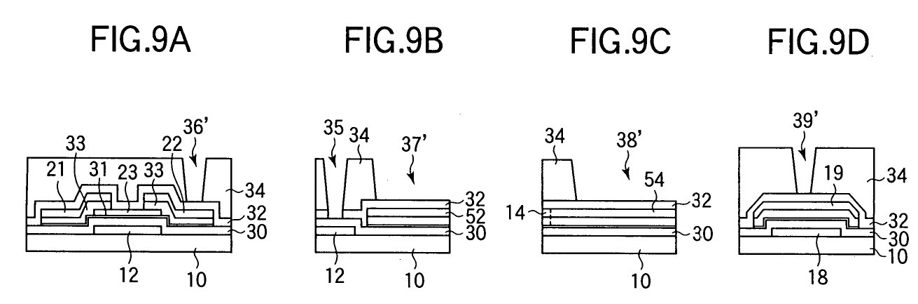

Referring to FIGS. 5A to 5D and FIG. 6 again, dry etching of the protective film 32 and the insulation film 30 is performed using the resist pattern 34 formed with the recessed portions 36, 37, 38 and 39 as a mask. For example, the dry etching is performed according to the RIE (Reactive Ion Etching) method or PE (Plasma Etching) method using a fluorine type mixed gas such as SF₆/O₂ or CF₄/O₂. At this time, the resist pattern 34 which is an organic film is simultaneously etched to a smaller thickness because of the nature of dry etching. Therefore, as shown in FIGS. 9A to 9D, the recessed portions 36, 37, 38 and 39 are etched away, and openings 36′, 37′, 38′ and 39′ are formed. After the openings 36′, 37′, 38′ and 39′ are formed, etching is started on the protective film 32 which is exposed at the openings 36′, 37′, 38′ and 39′. Thus, the start of etching of the protective film 32 above the source electrodes 22, the gate bus line terminals 52, the drain bus line terminals 54 and the storage capacitor electrodes 19 can be delayed.

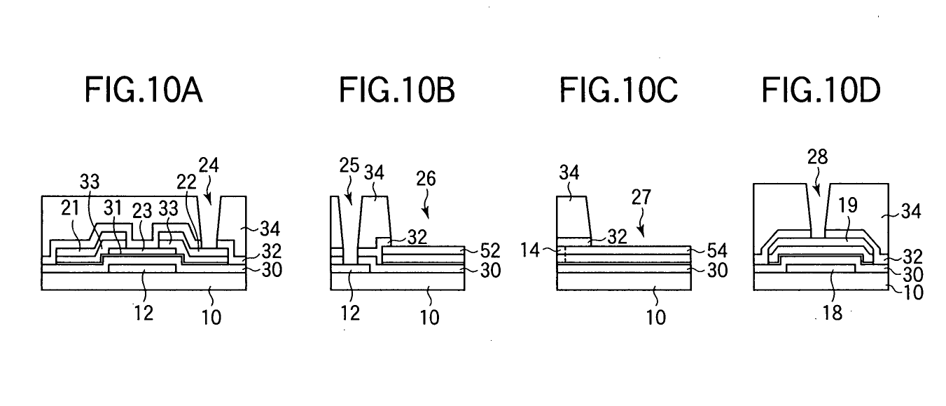

When the etching of the protective film 32 above the source electrodes 22, the gate bus line terminals 52, the drain bus line terminals 54 and the storage capacitor electrodes 19 is started, the protective film 32 has already been etched away at least in part of regions thereof located above the gate bus lines 12 which had been exposed through the openings 35. It is thus possible to reduce a difference between the time of formation of the contact holes (first contact regions) 25 that is the end of etching of the protective film 32 and the insulation film 30 above the gate bus lines 12 and the time of formation of the contact holes (second contact regions) 24, 26, 27 and 28 that is the end of etching of the protective film 32 above the source electrodes 22, the gate bus line terminals 52, the drain bus line terminals 54 and the storage capacitor electrodes 19 (see FIGS. 10A to 10D). The etching of the protective film 32 and the insulation film 30 above the gate bus lines 12 and the etching of the protective film 32 above the source electrodes 22, the gate bus line terminals 52, the drain bus line terminals 54 and the storage capacitor electrodes 19 can be finished substantially at the same time by adjusting the thickness of the recessed portions 36, 37, 38 and 39 of the resist pattern 34 or the ratio of the etching rate of the protective film 32 and the insulation film 30 to that of the resist pattern 34. The thickness of the recessed portions 36, 37, 38 and 39 can be adjusted by changing the thickness of the resist layer applied or formed, the dose of UV light, or the light transmittance of the semi-transmissive regions of the photo-mask 40 or 40′.

A method other than that described above may be used at the steps shown in FIGS. 5A to 5D and FIG. 9A to 10D. Specifically, after wet etching is performed using, for example, a hydrofluoric acid to remove at least the surface of the protective film 32 in the regions thereof exposed at the openings 35 (or removing the entire protective film 32 and part of the insulation film 30), the etching process is suspended. Then, the resist pattern 34 is ashed until the recessed portions 36, 37, 38 and 39 are removed to form the openings 36′, 37′, 38′ and 39′. The etching process is thereafter resumed to form the contact holes 24, 25, 26, 27 and 28. According to this method, since the recessed portions 36, 37, 38 and 39 are forcibly removed through ashing, it is easier to finish the etching of the protective film 32 and the insulation film 30 above the gate bus lines 12 and the etching of the protective film 32 above the source electrodes 22, the gate bus line terminals 52, the drain bus line terminals 54 and the storage capacitor electrodes 19 substantially simultaneously.

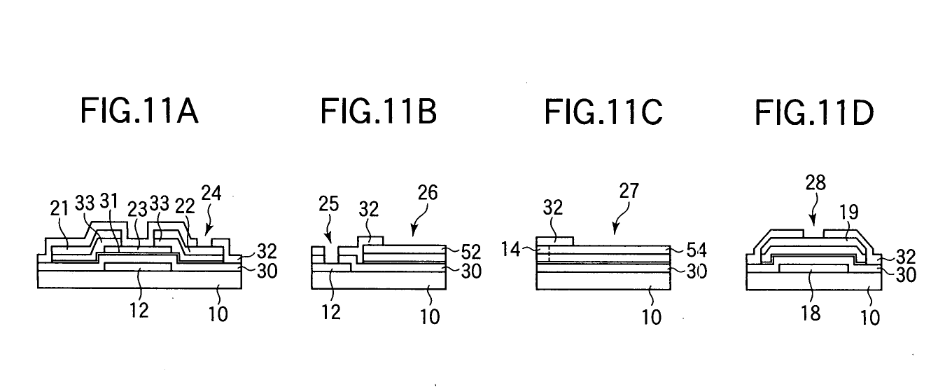

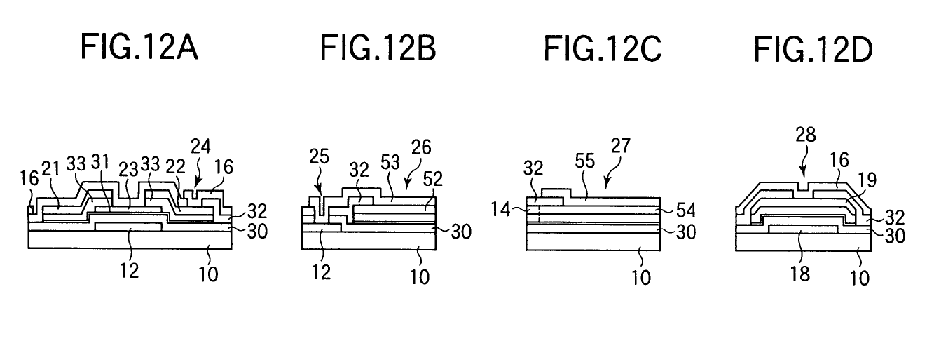

Next, the resist pattern 34 is peeled off as shown in FIGS. 11A to 11D. A transparent conductive film (not shown) is then formed throughout the substrate over the protective film 32. Subsequently, the transparent conductive film is patterned using a fifth photo-mask to form pixel electrodes 16, protective conductive films 53 on the gate bus line terminals 52 and protective conductive films 55 on the drain bus line terminals 54, as shown in FIGS. 12A to 12D. The pixel electrodes 16 are electrically connected to the source electrodes 22 through the contact holes 24 and are electrically connected to the storage capacitor electrodes 19 through the contact holes 28. The protective conductive films 53 are electrically connected to the gate bus lines 12 through the contact holes 25 and are electrically connected to the gate bus line terminals 52 through the contact holes 26. The protective conductive films 55 are electrically connected to the drain bus line terminals 54 through the contact holes 27. A TFT substrate 2 is completed through the above-described steps. In the present embodiment, there will be no increase in manufacturing steps because the TFT substrate 2 can be manufactured using a process employing five masks as done in the related art.

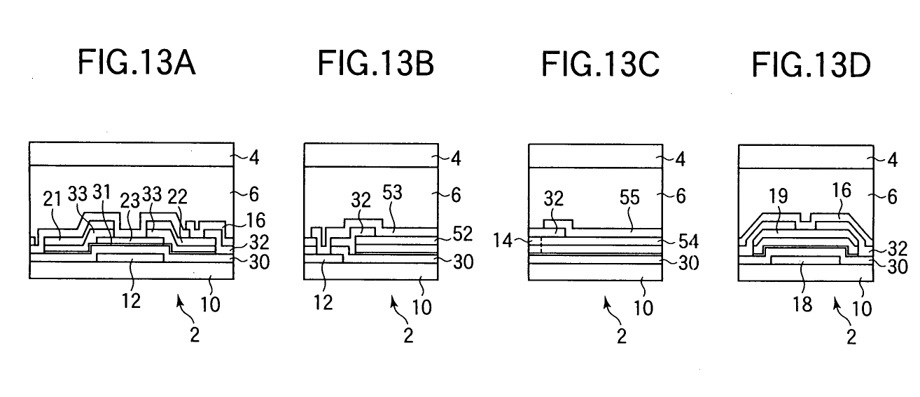

Next, as shown in FIGS. 13A to 13D, an opposite substrate 4 having a CF layer and a common electrode (both are not shown) formed thereon is combined with TFT substrate 2, and a liquid crystal 6 is sealed between the substrates 2 and 4. A liquid crystal display is completed through the above-described steps.

According to the present embodiment, it is possible to reduce a difference between the time of formation of the contact holes 25 that is the end of etching of the protective film 32 and the insulation film 30 above the gate bus lines 12 and the time of formation of the contact holes 24, 26, 27 and 28 that is the end of etching of the protective film 32 above the source electrodes 22, the gate bus line terminals 52, the drain bus line terminals 54 and the storage capacitor electrodes 19. It is therefore possible to reduce the time during which the surfaces of the source electrodes 22, the gate bus line terminals 52, the drain bus line terminals 54 and the storage capacitor electrodes 19 exposed as a result of the formation of the respective contact holes 24, 26, 27 and 28 (or the surfaces of the gate bus lines 12 exposed at the contact holes 25) are laid bare to etching plasma. Since this makes it possible to reduce damage on the surfaces of the source electrodes 22, the gate bus line terminals 52, the drain bus line terminals 54 and the storage capacitor electrodes 19 due to etching plasma, contact resistance between those elements and the pixel electrodes 16 and protective conductive films 53 and 55 formed thereon can be reduced. Further, since the thickness of the source electrodes 22, the gate bus line terminals 52, the drain bus line terminals 54 and the storage capacitor electrodes 19 serving as etching stoppers can be small, an improvement of productivity and a reduction in manufacturing cost can be achieved.

Further, in the present embodiment, since there is no increase in the size of the contact holes 24 and 28 attributable to overetching, the size of the patterns of the source electrodes 22 and the storage capacitor electrodes 19 serving as etching stoppers can be small. It is therefore possible to improve the aperture ratio of pixels and to improve the luminance and definition of a liquid crystal display.

[Second Embodiment]

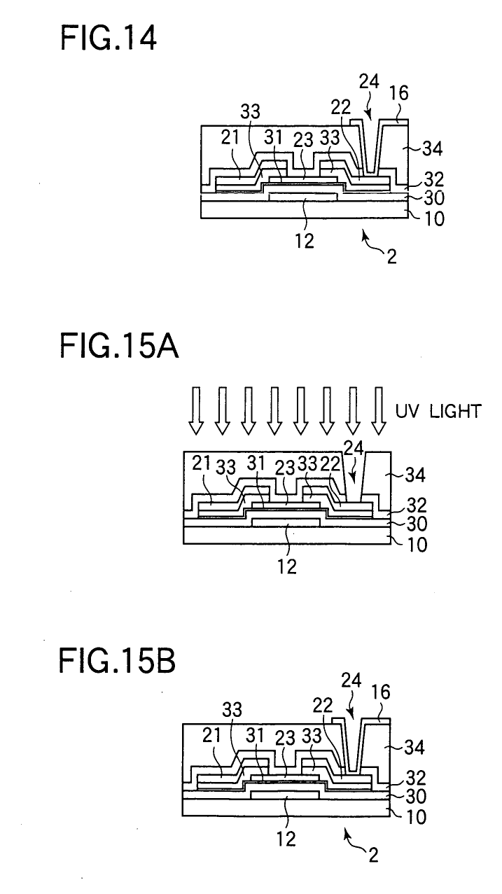

A method of manufacturing a substrate for a display according to a second embodiment of the invention will now be described with reference to FIGS. 14, 15A and 15B. FIG. 14 is a sectional view in the neighborhood of a TFT 20 taken in a process showing the method of manufacturing a substrate for a display according to the present embodiment. The description will omit steps up to the formation of contact holes 24, 25, 26, 27 and 28 using a resist pattern 34 formed with recessed portions 36, 37, 38 and 39 because they are similar to those in the first embodiment shown in FIGS. 2A to 10D. In the present embodiment, the resist pattern 34 used for the formation of the contact holes 24, 25, 26, 27 and 28 is not peeled off, and a transparent conductive film is formed throughout the substrate over the resist pattern 34. Subsequently, as shown in FIG. 14, the transparent conductive film is patterned using a fifth photo-mask to form protective conductive films 53 (not shown) on pixel electrodes 16 and gate bus line terminals 52 and protective conductive films 55 (not shown) on drain bus line terminals 54. A TFT substrate 2 is completed through the above-described steps.

In the present embodiment, the resist pattern 34 is left instead of being peeled off to use it as an overcoat layer (third insulation layer). The thickness of the overcoat layer can be adjusted by changing the thickness of the resist layer applied or formed, the dose of UV light or the light transmittance of semi-transmissive regions of a photo-mask 40 or 40′. The overcoat layer is characterized in that it can be easily formed with a great thickness compared to a protective film 32 and in that it has a small relative dielectric constant. This makes it possible to reduce parasitic capacitances which can degrade TFT characteristics. The manufacturing steps can be simplified because the resist pattern 34 used for the formation of the contact holes 24, 25, 26, 27 and 28 is used as an overcoat layer instead of peeling it off.

FIGS. 15A and 15B are sectional views taken in processes showing a modification of the method of manufacturing a substrate for a display according to the present embodiment. In the present modification, a positive acrylic photosensitive insulating resin is used as a material to form a resist pattern 34. As shown in FIG. 15A, before a transparent conductive film is formed, the resist pattern 34 is subjected to a bleaching process in which it is irradiated with UV light (e.g., i-rays having a wavelength of 365 nm). As a result of the bleaching process, the resist pattern 34 made of an acrylic photosensitive insulating resin becomes transparent. Then, a transparent conductive film is formed throughout the substrate over the resist pattern 34. Subsequently, the transparent conductive film is patterned using a fifth photo-mask to form pixel electrodes 16 and so on as shown in FIG. 15B. A TFT substrate 2 is completed through the above-described steps. In this modification, since the resist pattern 34 that is used as an overcoat layer is made transparent, a liquid crystal display having higher display quality can be provided.

[Third Embodiment]

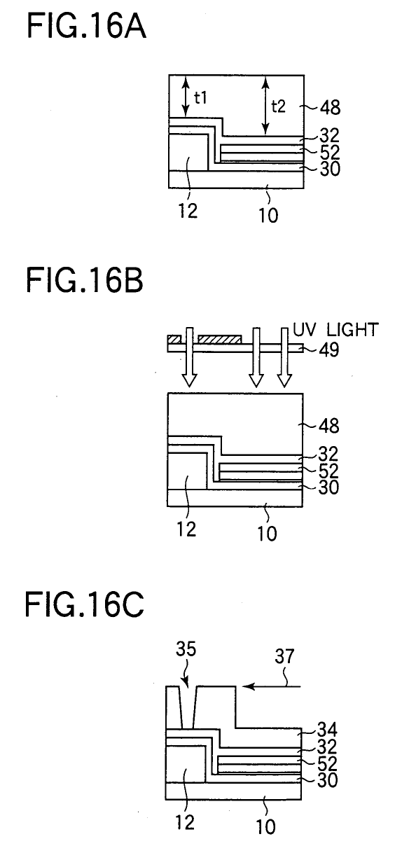

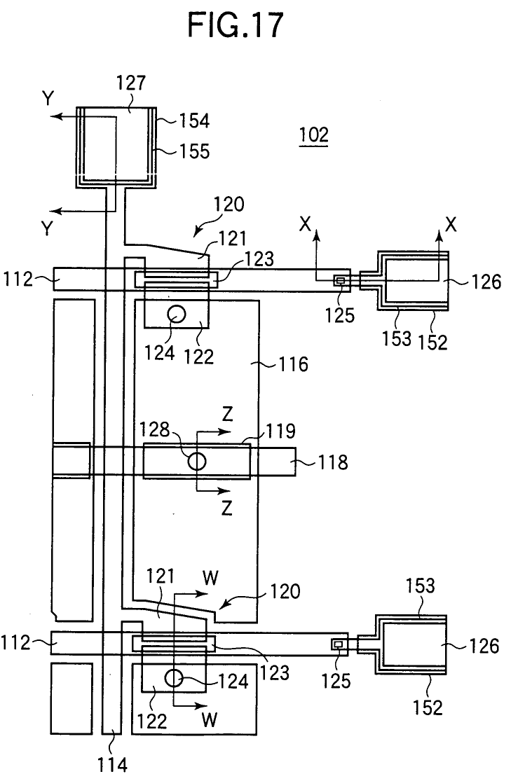

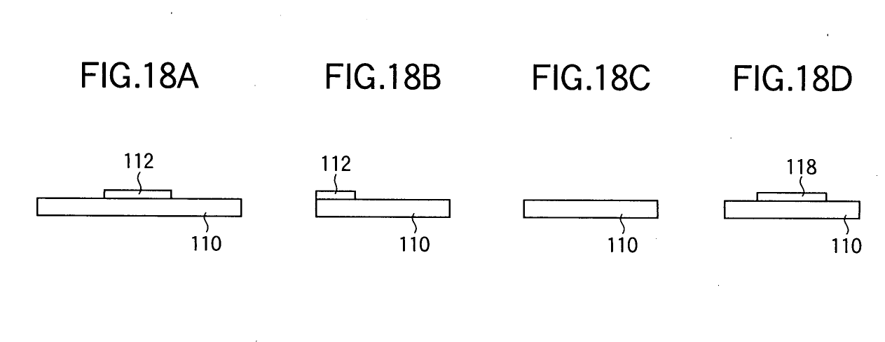

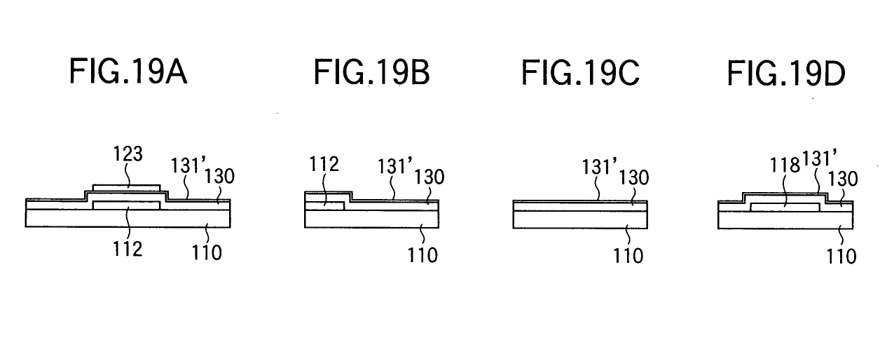

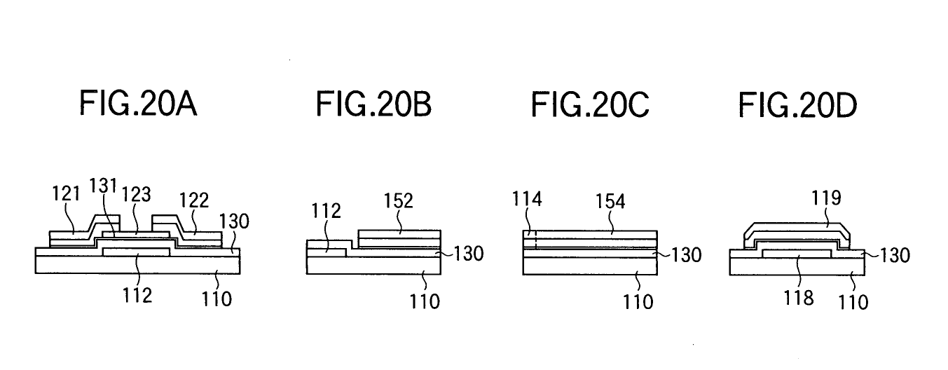

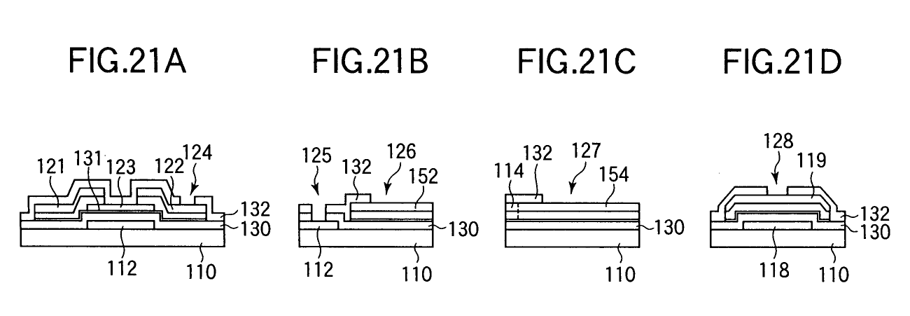

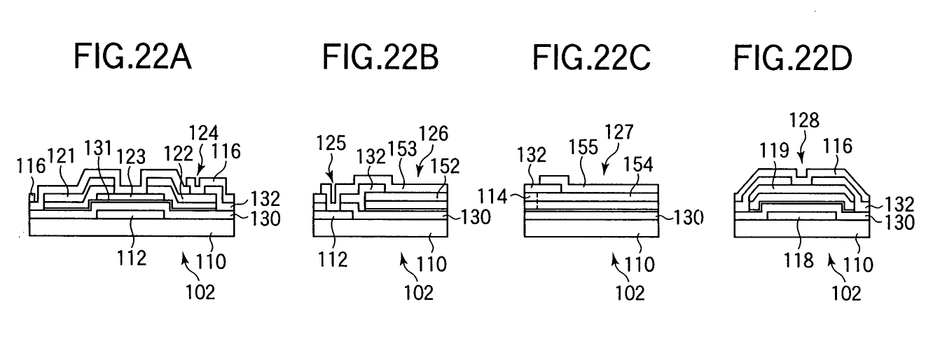

A method of manufacturing a substrate for a display according to a third embodiment of the invention will now be described with reference to FIGS. 16A to 16C. FIGS. 16A to 16C are sectional views in the neighborhood of a gate bus line terminal 52 taken in processes showing the method of manufacturing a substrate for a display according to the present embodiment. As shown in FIG. 16A, gate bus lines 12 (and storage capacitor bus lines 18 which are not shown) are formed with a relatively great thickness. The gate bus lines 12 are formed with a thickness greater than that of the gate bus line terminals 52 which are formed by stacking an a-Si film, an n⁺ a-Si film and a metal layer one over another at a later step. Thereafter, the gate bus line terminals 52, TFTs 20 and so on are formed in a manner similar to that in the first embodiment shown in FIGS. 3A to 4D. Next, a protective film 32 is formed throughout the substrate over the gate bus line terminals 52. At this time, the height of the surface of the protective film 32 above the glass substrate 10 in the regions thereof located above the gate bus lines 12 is greater than the height of the surface of the protective film 32 above the glass substrate 10 in other regions thereof such as the regions thereof located above the gate bus line terminals 52. Next, a positive photosensitive resist is applied to the entire surface of the protective film 32 to form a resist layer 48. Because of a leveling effect of the photosensitive resist, the resist layer 48 is formed with a thickness that varies from region to region in accordance with differences between the thicknesses of structures such as wirings. Specifically, a thickness t2 of the resist layer 48 above the gate bus line terminals 52 (and above source electrodes 22, drain bus line terminals 54 and storage capacitor electrodes 19 which are not shown) is greater than a thickness t1 of the resist layer 48 on the gate bus lines 12 (t2>t1).

Next, as shown in FIG. 16B, an exposure step is performed in which the resist layer 48 is irradiated with UV light through a photo-mask 49 having no semi-transmissive region unlike the photo-masks 40 and 40′ shown in FIGS. 7 and 8. At this exposure step, exposure is performed with such a dose that the regions of the resist layer 48 (having the thickness t1) above ends of the gate bus lines 12 are substantially completely exposed and such that the regions of the resist layer 48 (having the thickness t2) above the gate bus line terminals 52 are not completely exposed. Thus, the resist layer 48 is underexposed above the gate bus line terminals 52, and only part (the surface) of the same is exposed.

When the resist layer 48 is developed, as shown in FIG. 16C, the regions of the resist layer 48 above the ends of the gate bus lines 12 are all removed to form openings 35, and only the surface of the regions of the resist layer 48 above the gate bus line terminals 52 (and above the source electrodes 22, the drain bus line terminals 54 and the storage capacitor electrodes 19 which are not shown) is removed to form recessed portions 37 (and recessed portions 36, 38 and 39 which are not shown). Thereafter, a TFT substrate 2 is completed through steps similar to those in the first embodiment as shown in FIGS. 9A to 12D. The present embodiment provides advantages as those of the first embodiment using the photo-mask 49 having no semi-transmissive regions.

The invention is not limited to the above-described embodiments and may be modified in various ways.

For example, while a positive resist was referred to as an example of a material to form the resist pattern 34 in the above-described embodiment, the invention is not limited to the same, and a negative resist may be used as a material to form the resist pattern 34.

While methods of manufacturing a transmissive liquid crystal display were described by way of example in the above embodiments, the invention is not limited to them and may be applied to methods of manufacturing other types of liquid crystal displays such as reflective types and transflective types.

While methods of manufacturing a liquid crystal display were described by way of example in the above embodiments, the invention is not limited to them and may be applied to the manufacturing method for other types of displays such as organic EL displays and inorganic EL displays.

1. A method of manufacturing a substrate for a display, comprising the steps of:
forming a first electrode layer having a predetermined shape on a base substrate;
forming a first insulation layer on the first electrode layer;
forming a second electrode layer having a predetermined shape on the first insulation layer;
forming a second insulation layer on the second electrode layer;
forming a resist layer on the second insulation layer;
forming a resist pattern having a predetermined shape by patterning the resist layer;
forming a first contact region in which the first electrode layer is exposed by removing the first and second insulation layers using the resist pattern; and
forming a second contact region in which the second electrode layer is exposed by removing the second insulation layer using the resist pattern,
wherein the step of forming the resist pattern removes the resist layer on the first contact region and forms the resist pattern on the second contact region with a thickness smaller than the thickness of the resist pattern in other regions.

2. A method of manufacturing a substrate for a display according to claim 1, wherein the step of forming the resist pattern includes the step of performing halftone exposure.

3. A method of manufacturing a substrate for a display according to claim 2, wherein:
a positive resist is used as a material to form the resist layer; and
the step of performing halftone exposure exposes the resist layer on the second contact region with a dose of exposure smaller than that for the resist layer on the first contact region.

4. A method of manufacturing a substrate for a display according to claim 2, wherein the step of performing halftone exposure utilizes a photo-mask having a light-blocking region which blocks light, a transmissive region which transmits light and a semi-transmissive region which transmits light with a light transmittance lower than the light transmittance in the transmissive region.

5. A method of manufacturing a substrate for a display according to claim 1, wherein the step of removing the first and second insulation layers employs dry etching.

6. A method of manufacturing a substrate for a display according to claim 5, wherein the step of removing the first and second insulation layers also removes the resist pattern on the second contact region.

7. A method of manufacturing a substrate for a display according to claim 6, wherein the first insulation layer on the first contact region and the second insulation layer on the second contact region are substantially simultaneously removed.

8. A method of manufacturing a substrate for a display according to claim 5, wherein a fluorine type gas is used as an etchant for the dry etching.

9. A method of manufacturing a substrate for a display according to claim 1, wherein the step of removing the first and second insulation layers includes:
a step of performing ashing to remove the resist pattern on the second contact region after removing at least the surface of the second insulation layer on the first contact region; and
a step of removing the first and/or second insulation layer on the first contact region and the second insulation layer on the second contact region after the step of removing the resist pattern by performing ashing.

10. A method of manufacturing a substrate for a display according to claim 1, wherein the resist pattern is left to be used as a third insulation layer instead of being peeled off.

11. A method of manufacturing a substrate for a display according to claim 10, further comprising a process of bleaching the resist pattern.

12. A method of manufacturing a substrate for a display according to claim 10, wherein an acrylic photosensitive resin is used as a material to form the resist pattern.

13. A method of manufacturing a substrate for a display according to claim 1, wherein:
a positive resist is used as a material to form the resist layer;
the step of forming the resist layer forms the resist layer on the second contact region with a thickness greater than the thickness of the resist layer on the first contact region; and
the step of forming the resist pattern includes the step of performing exposure with such a dose of exposure that the resist layer on the first contact region is substantially completely exposed and such that the resist layer on the second contact region is not completely exposed.

14. A method of manufacturing a display having at least one substrate, wherein the substrate is fabricated using a method of manufacturing a substrate for a display according to claim 1.
